(19) United States
(12) Patent Application Publication
(10) Pub. No.: US 2012/0164418 A1
(43) Pub. Date: Jun. 28, 2012

(54) ARTICLE HAVING HARD FILM AND METHOD FOR MAKING THE ARTICLE

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); LI-QUAN PENG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/164,278

(22) Filed: Jun. 20, 2011

(30) Foreign Application Priority Data
Dec. 24, 2010 (CN) 201010606757.7

(51) Int. Cl. B32B 7/02; B32B 15/04; B32B 3/00; C23C 14/34; B32B 9/04

(52) U.S. Cl. 428/216; 204/192.1; 428/704; 428/220; 428/336; 428/457

(57) ABSTRACT

An article includes a substrate and a hard film formed on the substrate. The hard film includes a plurality of TiAlN layers and a plurality of BN layers, each BN layer and each TiAlN layer is alternately arranged. The disclosure also describes a method to make the article.

### CROSS-REFERENCE TO RELATED APPLICATIONS

This application is related to co-pending U.S. Patent Application (Attorney Docket No. US36050) entitled “ARTICLE HAVING HARD FILM AND METHOD FOR MAKING THE ARTICLE”. Such application has the same assignee as the present application. The above-identified application is incorporated herein by reference.

### BACKGROUND

1. Technical Field

The present disclosure relates to an article having a hard film and a method for making the article.

2. Description of the Related Art

Hard films are widely applied on the surface of the metal alloys, steels and ceramics to fabricate articles with a high hardness and a high abrasion resistance. Currently, a common hard film is TiAlN film. However, to meet the needs for maximum hardness for special articles, such as cutting tools, the TiAlN film does not meet this requirement for hardness and abrasion resistance.

Therefore, there is room for improvement within the art.

### BRIEF DESCRIPTION OF THE DRAWINGS

Many aspects of the present disclosure article having hard film and method for making the article can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a sectional view of an article having hard film according to an exemplary embodiment.

FIG. 2 is a flow chart to fabricate the article shown in FIG. 1.

FIG. 3 is a vertical view of a coating machine used to fabricate the article.

### DETAILED DESCRIPTION

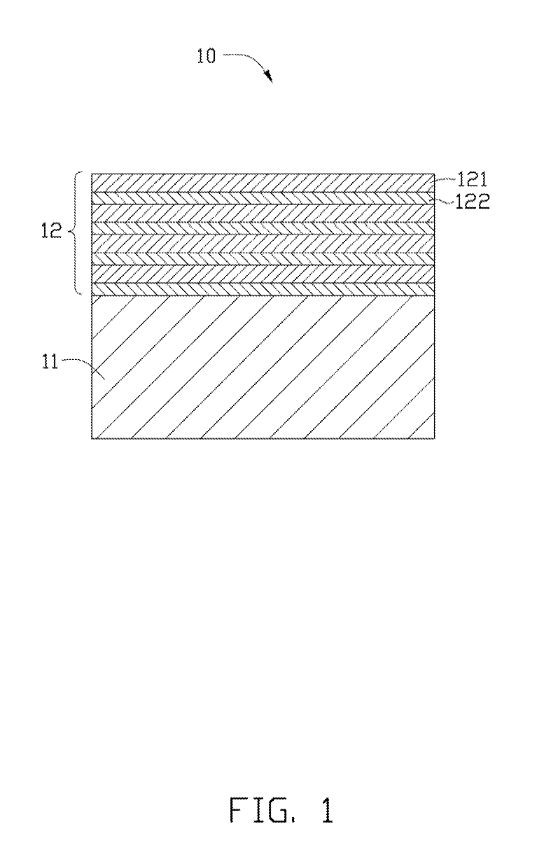

FIG. 1 shows an exemplary embodiment of an article 10. The article 10 includes a substrate 11 and a hard film 12 integrally formed on the external surface of the substrate 11. The substrate 11 can be, for example, metal alloy, stainless steel, or ceramic.

The hard film 12 can be formed on the substrate 11 by Physical Vapor Deposition (PVD). The hard film 12 includes a plurality of alternating TiAlN layers 121 and BN layers 122, and each BN layer 122 is alternately arranged with each TiAlN layer 121. Because the thermal expansion rate of the BN layer 122 is close in value to the thermal expansion rate of the substrate 11, a BN layer 122 is directly formed on an outer surface of the substrate 11, thus avoiding the production of large inner stresses during variations in the temperature of the article 10. The TiAlN layer 121 has excellent hardness, thus, a TiAlN layer 121 is made the outermost layer of the article 10. Each TiAlN layer 121 and each BN layer 122 has uniform thickness ranging from 3 nanometer (nm)-15 nm. The hard film 12 has a total thickness ranging from 1 micrometer (μm)-2.5 μm.

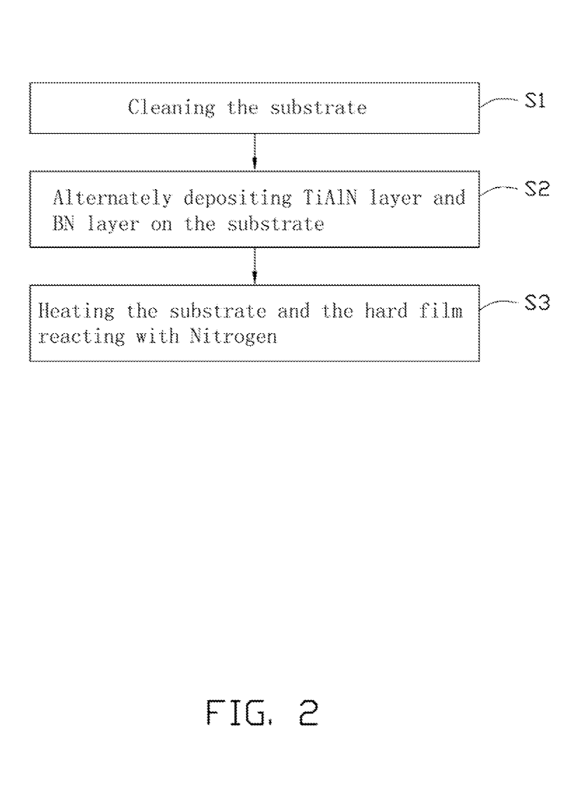

Referring to FIG. 2, the article 10 can be made from following steps:

Step 1: the substrate 11 is provided and can be metal alloy, steel, or ceramic. The substrate 11 is cleaned by a cleaning solution to clean grease from the surface of the substrate 11. The cleaning solution can be ethanol, acetone and/or other organic solvents. A common ultrasonic cleaning machine can be used for cleaning the substrate 11.

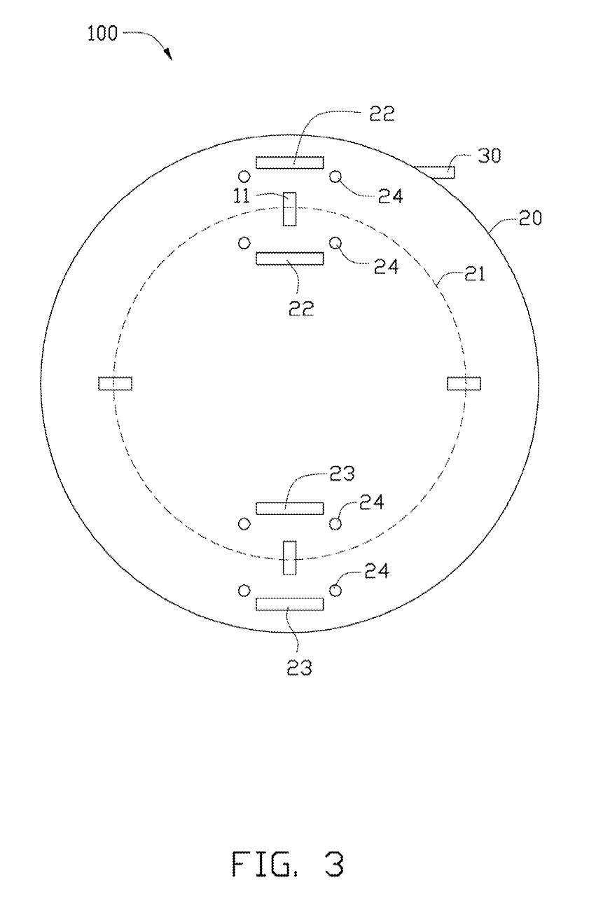

Step 2: the substrate 11 is processed by PVD to form the hard film 12 on the surface. Referring to FIG. 3, a vacuum sputtering coating machine 100 includes a sputtering coating chamber 20 and a vacuum pump 30 connecting to the sputtering coating chamber 20. The vacuum pump 30 is used to pump air out from the sputtering coating chamber 20. The vacuum sputtering coating machine 100 further includes a rotating bracket 21, two first targets 22, two second targets 23 and a plurality of gas inlets 24. The rotating bracket 21 rotates the substrate 11 in the sputtering coating chamber 20 relative to the first targets 22 and the second targets 23. The first targets 22 face each other, and are respectively located on opposite sides of the rotating bracket 21. The second targets 23 face each other, and are respectively located on opposite sides of the rotating bracket 21. In this exemplary embodiment, the first targets 22 are TiAl alloy targets. The second targets 23 are BN targets.

The first targets 22 and the second targets 23 are plasma cleaned first. The vacuum level inside the sputtering coating chamber 20 is set to about 3.0*10⁻³ Pa. Argon (Ar) is fed into the sputtering coating chamber 20 at a flux rate about 500 Standard Cubic Centimeters per Minute (sccm) from the gas inlets 24. A bias voltage applied to the substrate 11 may be between about −250 volts (V) and about −350 volts. Each first targets 22 and each second targets 23 in the sputtering coating chamber 20 is evaporated at a power between about 300 watt (W) and about 500 W. The Ar particles strike against and clean the surface of the first targets 22 and the second targets 23.

The hard film layer 12 is deposited on the substrate 11 second. The vacuum level inside the sputtering coating chamber 20 is set to about 3.0*10⁻³ Pa. The temperature in the sputtering coating chamber 20 is set between about 20° C. (Celsius degree) and about 300° C. A bias voltage applied to the substrate 11 is adjusted to between about −100 volts and about −300 volts. Argon(Ar) and Nitrogen(N₂) are fed into the sputtering coating chamber 20, with Argon at a flux rate about 300 sccm, and Nitrogen at a flux between about 70 sccm and about 130 sccm. The first targets 22 in the sputtering coating chamber 20 are evaporated at a power between about 400W and about 500W. The second targets 23 in the sputtering coating chamber 20 are evaporated at a power between about 300W and about 400W. The rotating bracket 21 is started at a speed between about 2 revolutions per minute(r/min) and about 5 r/min. A bias voltage applied to the substrate 11 may be between about −250 volts (V) and about −350 volts, for between about 30 minutes and about 120 minutes, to deposit the hard film 12 on the substrate 11, thus the article 10 is formed.

During depositing to the hard film 12, the TiAlN layers 121 and the BN layer 122 are alternately deposited. Each TiAlN layer 121 and each BN layer 122 has a uniform thickness ranging from about 3 nanometer (nm) to about 15 nm, the hard film 12 has a total thickness in range from 1 (μm) to 2.5 μm. The substrate 11 directly contacts a BN layer 122. The outermost layer of the article 10 is the TiAlN layer 121.

The second target 23 utilizes BN material, not Elemental B because: Elemental B has a weak electrical conducting performance and Elemental B needs a high temperature reaching 2000 Celsius degree (° C.) to sputter. Additionally, the particles of Elemental B are hard to combine with N particles to form BN particles by sputtering. However, BN material can sputter at about 700° C.

The hard film 12 formed by alternately depositing TiAlN layer 121 and BN layers 122 has an improved hardness and the abrasion resistance relative to the TiAlN film. The hardness of a material mainly depends on how easily the microscopic particles inside the material move. When the particles move more easily, the material extends more easily and has a weak hardness, and vice versa. In present exemplary embodiment, the TiAlN layers 121 and BN layers 122 are alternately deposited, moreover, the TiAlN layer 121 and BN layer 122 are thin, thus, TiAlN particles and BN particles are easily mismatched at the combining surface of the TiAlN layer 121 with BN layer 122. The TiAlN particles and the BN particles are intermingled and obstruct each other, thus, stopping the particles from moving and resulting in an improved hardness for the article 10.

Step 3: the article 10 is modified by nitridation process. The article 10 is placed into an oven (not shown) for heating. The oven filled with Nitrogen, with a temperature in the oven is set between about 500° C. and about 800° C. The hard film 12 substantially reacts with the Nitrogen, after between about 40 minutes and about 80 minutes. The hard film 12 reacts completely and forms the TiAlN particles and BN particles. Additionally, the TiAlN particles and the BN particles are further intermingled with each other in a more suitable temperature of 500-800° C. Therefore, the hard film 12 further improves the hardness and abrasion resistance of the article 10.

It is to be understood that even though numerous characteristics and advantages of the present embodiments have been set forth in the foregoing description, together with details of assemblies and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. An article, comprising:
a substrate; and
a hard film formed on the substrate;
wherein the hard film includes a plurality of alternating TiAlN layers and BN layers.

2. The article as claimed in claim 1, wherein each TiAlN layer and each BN layer has a uniform thickness ranging from 3 nm-15 nm.

3. The article as claimed in claim 1, wherein the hard film has a total thickness ranging from 1 μm-2.5 μm.

4. The article as claimed in claim 1, wherein the ceramic layer has a thickness ranging from 0.18 mm-0.4 mm.

5. The article as claimed in claim 1, wherein a BN layer is directly directly formed on a surface of the substrate.

6. The article as claimed in claim 1, wherein a TiAlN layer is the outermost layer of the article.

7. The article as claimed in claim 1, wherein the substrate is chosen from a metal alloy, stainless steel, and ceramic.

8. A method for making an article having a hard film, comprising:
providing a substrate;
providing a vacuum sputtering coating machine including a sputtering coating chamber having rotating bracket, TiAlN targets and BN targets set therein, the vacuum sputtering coating machine being used to depositing the hard film;
alternately depositing TiAlN layers and BN layers on the substrate by vacuum sputtering to form the hard film on the substrate;
further modifying the hard film via nitridation process.

9. The method of claim 8, wherein during alternately depositing the TiAlN layers and the BN layers, the vacuum level inside the sputtering coating chamber is set to about 3.0×10⁻³ Pa, argon is fed into the sputtering coating chamber at a flux about 300 sccm, nitrogen is fed into the sputtering coating chamber at a flux between about 70 sccm and about 130 sccm; TiAl targets is evaporated at a power between about 400W and about 500W, BN targets is evaporated at a power between about 300W and about 400W, the speed of the rotating bracket is set about 2-5 r/min; a bias voltage applied to the substrate is between about −250 volts and about −350 volts, for between about 30 minutes and about 120 minutes, to deposit the hard film on the substrate.

10. The method of claim 8, wherein before alternately depositing the TiAlN layers and the BN layers, to clean TiAl targets and BN targets, the vacuum level inside the sputtering coating chamber is set to about 3.0×10⁻³ Pa, argon is fed into the sputtering coating chamber at a flux about 500 sccm, a bias voltage applied to the substrate between about −250 V and about −350 V, the TiAl targets and the BN targets are evaporated at a power between about 300 W and about 500 W respectively.

11. The method of claim 8, wherein during modifying the hard film via nitridation process, placing the substrate into an oven for between about 20 minutes and about 40 minutes, the oven filled with Nitrogen, the temperature in the oven is set between about 500° C. and about 800° C.
